(19) United States
(12) Patent Application Publication
(10) Pub. No.: US 2008/0294282 A1
(43) Pub. Date: Nov. 27, 2008

(54) USE OF LOGICAL LOTS IN SEMICONDUCTOR SUBSTRATE PROCESSING

(75) Inventors: Sushant S. Koshti, Sunnyvale, CA (US); Vinay K. Shah, San Mateo, CA (US); Eric A. Englhardt, Palo Alto, CA (US)

Correspondence Address: DUGAN & DUGAN, PC, 245 Saw Mill River Road, Suite 309, Hawthorne, NY, 10532, US

(73) Assignee: Applied Materials, Inc., Santa Clara, CA (US)

(21) Appl. No.: 12/126,880

(22) Filed: May 24, 2008

Related U.S. Application Data
(60) Provisional application No. 60/940,075, filed on May 24, 2007.

(51) Int. Cl. H01L 21/67; G06F 17/00; H01L 21/677

(52) U.S. Cl. 700/121; 700/213; 700/226; 700/228

(57) ABSTRACT

In some embodiments, a method of processing substrates is provided that includes (1) grouping substrates in a plurality of substrate carriers as a logical lot; (2) processing the logical lot as if the substrates were stored in a single substrate carrier; and (3) performing metrology on a representative subset of substrates in the logical lot. Numerous other embodiments are provided.

The present application claims priority from U.S. Provisional Patent Application Ser. No. 60/940,075, filed May 24, 2007, which is hereby incorporated by reference herein in its entirety.

### FIELD OF THE INVENTION

The present invention relates to semiconductor device manufacturing and more particularly to managing lots of semiconductor substrates during device manufacturing.

### BACKGROUND OF THE INVENTION

Manufacturing of semiconductor devices typically involves performing a sequence of procedures with respect to a substrate such as a silicon substrate, a glass plate, etc. These steps may include polishing, deposition, etching, photolithography, heat treatment, and so forth. Usually a number of different processing steps may be performed in a single processing system or “tool” which includes a plurality of processing chambers. However, it is generally the case that other processes are required to be performed at other processing locations within a fabrication facility, and it is accordingly necessary that substrates be transported within the fabrication facility from one processing location to another. Depending upon the type of semiconductor device to be manufactured, there may be a relatively large number of processing steps required, to be performed at many different processing locations within the fabrication facility.

It is conventional to transport substrates from one processing location to another within substrate carriers such as sealed pods, cassettes, containers and so forth. It is also conventional to employ automated substrate carrier transport devices, such as automatic guided vehicles, overhead transport systems, substrate carrier handling robots, etc., to move substrate carriers from location to location within the fabrication facility or to transfer substrate carriers from or to a substrate carrier transport device.

For an individual substrate, the total fabrication process, from formation or receipt of the virgin substrate to cutting of semiconductor devices from the finished substrate, may require an elapsed time that is measured in weeks or months. In a typical fabrication facility, a large number of substrates may accordingly be present at any given time as “work in progress” (WIP). The substrates present in the fabrication facility as WIP may represent a large investment of working capital, which tends to increase the per substrate manufacturing cost. It would therefore be desirable to reduce the amount of WIP for a given substrate throughput for the fabrication facility. To do so, the total elapsed time for processing each substrate should be reduced.

### SUMMARY OF THE INVENTION

In a first embodiment of the invention, a first method of processing substrates is provided that includes (1) grouping substrates in a plurality of substrate carriers as a logical lot; (2) processing the logical lot as if the substrates were stored in a single substrate carrier; and (3) performing metrology on a representative subset of substrates in the logical lot.

In a second embodiment of the invention, a second method of processing substrates is provided that includes (1) grouping substrates of a plurality of small lot size substrate carriers as a logical lot and at least one sub-lot; (2) processing the logical lot as if the substrates were stored in a single substrate carrier; (3) simultaneously dispatching the substrate carriers of the sub-lot to a plurality of metrology tools; and (4) simultaneously performing metrology on a plurality of substrates of the substrate carriers of the sub-lot.

In a third embodiment of the invention, a third method of processing substrates is provided that includes (1) grouping substrates of a plurality of small lot size substrate carriers as a logical lot and at least one sub-lot; (3) dispatching the substrate carriers of the logical lot to a plurality of processing tools; and (4) simultaneously processing the logical lot at the plurality of processing tools. Numerous other aspects are provided.

Other features and aspects of the present invention will become more fully apparent from the following detailed description, the appended claims and the accompanying drawings.

### BRIEF DESCRIPTION OF THE FIGURES

FIG. 1 is a top view of an exemplary processing facility provided in accordance with the present invention.

FIG. 2 is an exemplary embodiment of the processing facility of FIG. 1 in which the processing tools are represented as one or more lithography tracks and one or more metrology tools.

FIG. 3 is a flowchart of a first exemplary method provided in accordance with the present invention.

FIG. 4 is a flowchart of a second exemplary method provided in accordance with the present invention.

FIG. 5 is a flowchart of a third exemplary method provided in accordance with the present invention.

### DETAILED DESCRIPTION

In accordance with one or more embodiments of the invention, substrates and/or substrate carriers may be organized into “logical lots”, to improve WIP management or otherwise affect substrate processing. For example, a logical lot may include a group of substrate carriers that contain substrates that are (1) to undergo one or more of the same or similar processes; and/or (2) to have the same or similar devices formed on the substrates.

In some embodiments, individual substrate carriers or “members” of a logical lot may be moved together for a specified number of process steps. A logical lot may be split across multiple tools for the same or for different process steps, as well as across transportation resources. Some members of a logical lot may skip specific steps or includes extra processing steps (e.g., metrology, rework, etc.). Further, the position of a member within a logical lot may be fixed or change (e.g., membership within a logical lot may be dynamic so that members may be added or removed).

A logical lot may be further subdivided into one or more sub-lots. For example, one or more members of a logical lot may form a sub-lot that is sent to metrology or another location. Sub-lots may permanently or temporarily leave a logical lot. In some embodiments, a sub-lot may include a single carrier and/or substrate. Members of a logical lot or sub-lot may be further associated with specific processing chambers within one or more process tools. Additionally, substrate carriers may be members of multiple logical lots.

As will be described further below, by employing logical lots and sub-lots, the waiting time for substrates during device fabrication (and/or in a substrate carrier) may be significantly reduced, as may overall cycle-time. Maintaining logical lot association allows processing tools to process a large number of substrates that require the same process or that have the same characteristics. In this manner, the setup overhead associated with a processing tool/process line may be reduced. Similarly, logical lot association allows communication overhead, especially the number of transactions, to be reduced, as single control commands, or a reduced number of control commands, may be used for most if not all substrates and/or substrate carriers of a logical lot.

### Exemplary Logic Lots

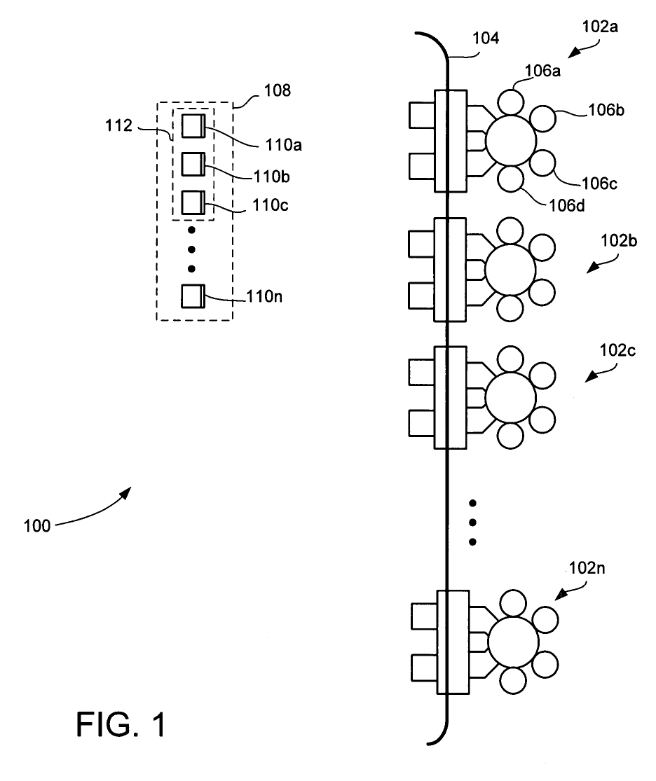

FIG. 1 is a top view of an exemplary processing facility 100 provided in accordance with the present invention. With reference to FIG. 1, the processing facility 100 includes a plurality of substrate processing tools 102a-n that are interconnected or otherwise coupled via an overhead or other transport system 104. The facility 100 may include fewer or more substrate processing tools, and/or more transport systems. The processing tools 102a-n may be adapted to perform the same or different processing steps; and adapted to perform any suitable processes (e.g., deposition, etching, cleaning, baking, cooling, lithography, and/or the like). In some embodiments, the processing tools 102a-n may include one or more processing chambers 106a-d. The particular processing tools 102a-n of FIG. 1 are illustrated as cluster tools although other tool configurations may be used (e.g., track layouts such as a lithography track, stand alone metrology tools, etc.).

The processing facility 100 also includes a logical lot 108 that includes substrate carriers 110a-n. A sub-lot 112 that includes carriers 110a-c is also shown. The logical lot 108 may include more than one sub-lot; and each sub-lot may include any number of substrate carriers (e.g., 1, 2, 3, 4, 5, 6, 7, etc.). Processing of the logical lot 108 may occur within one of the processing tools 102a-n, or in other embodiments, substrate carriers 110a-n within the logical lot 108 may be processed in multiple processing tools 102a-n and/or processing chambers 106a-d (e.g., in parallel).

In at least one embodiment of the invention, each substrate carrier 110a-n may be a small lot size carrier adapted to hold a maximum of 12 or fewer substrates. In other embodiments, each small lot size carrier may be adapted to hold a maximum of 6 or less, 5 or less, 4 or less, 3 or less, or 2 or less substrates.

In some embodiments, each physical and/or logical lot may be ultra-small (e.g., 1 or 2 substrates). For example, physical lot size may be defined by the size of the substrate carrier employed (e.g., 1, 2, 3, 4, 5, 6, etc., substrates per carrier). In general, logical lots may include substrate carriers of the same or differing sizes.

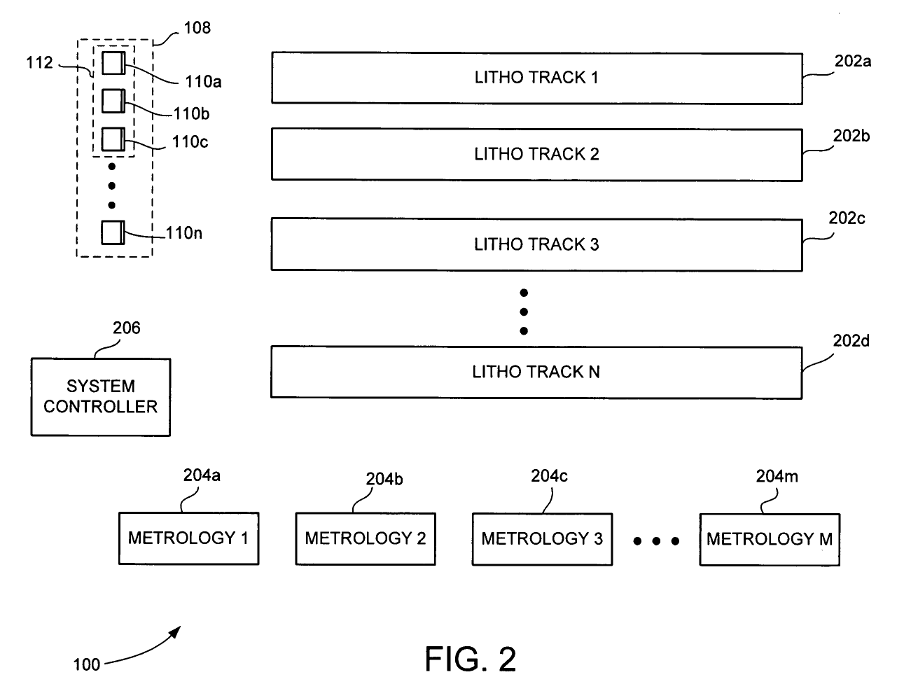

FIG. 2 is an exemplary embodiment of the processing facility 100 of FIG. 1 in which the processing tools 102a-n are represented as one or more lithography tracks 202a-n and one or more metrology tools 204a-m. Each lithography track 202a-n may include, for example, spinners for coating substrates with photoresist, heaters for pre-exposure bake, steppers for pattern exposure, heaters for post-exposure bake, development baths, heaters for post-development bake and/or the like. Each metrology tool 204a-m may perform one or more metrology measurements relevant to lithographic processing such as critical dimension (CD) measurement, pattern overlay checking, defect detection, etc. For convenience, the transport system 104 is not illustrated in FIG. 2.

### Logical Lot Processing at a Tool

In some embodiments, all members of the logical lot 108 may be processed in the same processing tool (e.g., a cluster-type processing tool 102a-n in FIG. 1, a lithography track 202a-n in FIG. 2, etc.). In such an embodiment, numerous scenarios may be employed to initiation substrate processing. For example, the processing tool in question may wait for all substrate carriers in a logical lot to arrive at the processing tool to prior to the start of processing. Alternatively, the processing tool may begin processing at a time determined to ensure that there will be no break in the processing pipeline. In another embodiment, the processing tool may begin processing after a pre-determined or pre-specified number of substrate carriers of the logical lot have been delivered to the processing tool.

Dispatching Logical Lot Members after Processing at Tool

A processing tool such as processing tool 102a-n, 202a-n may wait for all members of a logical lot to finish processing before dispatching one or more members of the logical lot, or the entire logical lot, to downstream tools or other processing stations. Alternatively, a processing tool may begin dispatching members of a logical lot after a certain number of members of the logical lot have finished processing. In one or more embodiments, members of a logical lot may be dispatched based on the processing order at the downstream tool (e.g., so that substrate carriers arrive at the downstream tool in the to-be-processed order). In some embodiments, members of a logical lot selected for metrology may or may not be dispatched immediately after processing.

As an example, with reference to FIG. 2, processing within lithography track 102a may occur after all substrate carriers 110a-n of logical lot 108 have arrived at the lithography track 102a, or after only some of the substrate carriers 110a-n of logical lot 108 have arrived at the lithography track 102a. Likewise, substrate carriers 110a-n of the logical lot 108 may be dispatched from the lithography track 102a to another tool, such as an etch tool, after all substrates within the logical lot 108 have been processed in the lithography track 102a or after only some have been processed.

### Order of Processing of Logical Lot Members at a Tool

The order of processing of members within a logical lot may be first-in-first out (FIFO), random, pre-determined or otherwise ordered. For example, substrate carriers 110a-n of logical lot 108 may be processed on a first-in-first out (FIFO) or random basis, or in any other order.

In cases in which all members of a logical lot or sub-lot are processed at different tools, the logical lot may be divided into one or more sub-lots and each sub-lot may be dispatched to a specific tool or tools for processing. There may be different sequencing rules at processing tools for different members within a sub-lot, similar to those applicable to logical lots (e.g., FIFO, random, pre-determined, etc.). Sub-lots, such as sub-lot 112, may recombine, if at all, after specific steps, or may continue to be processed separately for multiple steps.

### Dispatching Sub-Lots to Metrology Tools

When sub-lots of a logical lot are dispatched to a metrology tool, in some embodiments, not every substrate within the sub-lots needs metrology processing. For example, only one substrate, or fewer than all substrates, within a substrate carrier of a sub-lot may be analyzed at a metrology tool. Members of a sub-lot may be reordered based on metrology sampling requirements. Other members within the logical lot (or sub-lot) may wait for metrology results prior to another processing step being performed. Such waiting may be performed at (1) a previous processing tool; (2) a subsequent processing tool after dispatch; and/or (3) a stocker at the previous or subsequent processing tool. In other embodiments, substrates of a logical lot not sent to metrology may be processed without waiting for metrology results. For example, processing may start as soon as possible at one or more subsequent processing chambers and/or tools. Alternatively, processing may start at a computed time such that no gap in processing will occur due to sub-lots rejoining after metrology.

In some embodiments, logical lots and/or sub-lots may be routed sequentially to multiple metrology steps (and/or tools). Alternatively, logical lots and/or sub-lots may be routed in parallel to multiple metrology steps and/or tools. As an example, with reference to FIG. 2, after processing within one of the lithography tracks 202a-n, substrate carriers 110a-c of sub-lot 112 may be dispatched to metrology tools 204a-c, for example. Metrology tool 204a may measure CD of a substrate in substrate carrier 110a, metrology tool 204b may measure pattern overlay of a substrate in substrate carrier 110b and metrology tool 204c may measure defect density of a substrate in substrate carrier 110c, for instance. In at least one embodiment, such measurements may be performed at the same time (e.g., in parallel) to increase throughput. Such information may be fed back to a system or other controller 206, for example, and used to determine the quality and/or accuracy of the lithographic processing performed on the substrates of logical lot 108 (e.g., for rework decisions, subsequent processing decisions, etc.). Note that when small lot size substrate carriers are employed within the logical lot 108, such metrology analysis may be performed very quickly. After metrology, the carriers 110a-c from the sub-lot 112 may be returned to the logical lot 108. In some embodiments, as a result of metrology, for example, one or more substrate carriers may be removed or added to the logical lot 108 (e.g., removed to be reworked, added in after rework, etc.).

For multiple metrology steps and/or tools, substrate carriers may wait for all metrology steps to be completed, for specific metrology results or for a specific number of metrology results, prior to continuing processing.

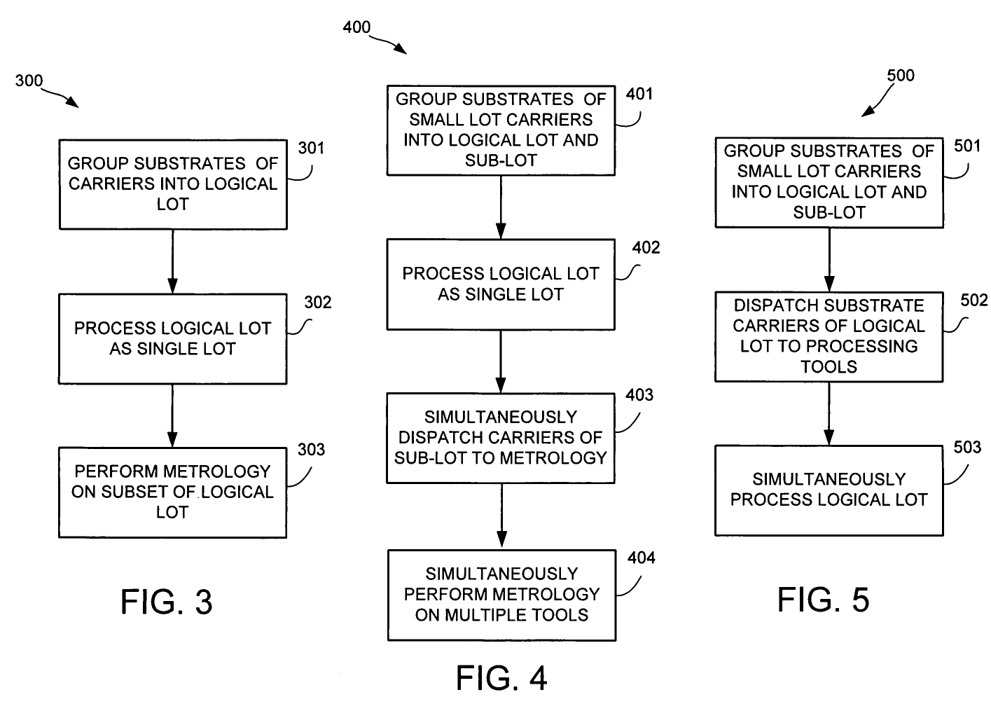

FIG. 3 is a flowchart of a first exemplary method 300 provided in accordance with the present invention. With reference to FIG. 3, in step 301, substrates in a plurality of substrate carriers are grouped as a logical lot. In step 302, the logical lot is processed as if the substrates were stored in a single substrate carrier (e.g., at a single processing tool or at multiple processing tools). In step 303, metrology is performed on a representative subset of substrates in the logical lot (e.g., at one or more metrology tools).

FIG. 4 is a flowchart of a second exemplary method 400 provided in accordance with the present invention. With reference to FIG. 4, in step 401, substrates of a plurality of small lot size substrate carriers are grouped as a logical lot and at least one sub-lot. In step 402, the logical lot is processed as if the substrates were stored in a single substrate carrier. In step 403, the substrate carriers of the sub-lot are simultaneously dispatched to a plurality of metrology tools. In step 404, metrology is performed simultaneously on a plurality of substrates of the substrate carriers of the sub-lot.

FIG. 5 is a flowchart of a third exemplary method 500 provided in accordance with the present invention. With reference to FIG. 5, in step 501, substrates of a plurality of small lot size substrate carriers are grouped as a logical lot and at least one sub-lot. In step 502, the substrate carriers of the logical lot are dispatched to a plurality of processing tools. In step 503, the logical lot is simultaneously processed at the plurality of processing tools.

The foregoing description discloses only exemplary embodiments of the invention. Modifications of the above disclosed apparatus and methods which fall within the scope of the invention will be readily apparent to those of ordinary skill in the art. For instance, the controller 206 or another controller may include computer program code for performing any of the methods and/or other scheduling and/or workflow management described herein.

Accordingly, while the present invention has been disclosed in connection with exemplary embodiments thereof, it should be understood that other embodiments may fall within the spirit and scope of the invention, as defined by the following claims.

The invention claimed is:

1. A method of processing substrates comprising:
grouping substrates in a plurality of substrate carriers as a logical lot;
processing the logical lot as if the substrates were stored in a single substrate carrier; and
performing metrology on a representative subset of substrates in the logical lot.

2. The method of claim 1 wherein each substrate carrier is a small lot size substrate carrier adapted to hold a maximum of 12 or fewer substrates.

3. The method of claim 2 wherein each substrate carrier is adapted to hold a maximum of 6 or fewer substrates.

4. The method of claim 3 wherein each substrate carrier is adapted to hold a maximum of 4 or fewer substrates.

5. The method of claim 1 wherein performing metrology on the representative subset of substrates in the logical lot includes:
dispatching one or more of the substrate carriers of the logical lot to one or more metrology tools; and
performing metrology on substrates within the one or more substrate carriers.

6. The method of claim 5 wherein dispatching one or more of the substrate carriers of the logical lot includes dispatching multiple substrate carriers of the logical lot, each to a different metrology tool.

7. The method of claim 6 wherein performing metrology on substrates within the one or more substrate carriers includes performing a different metrology process within each metrology tool.

8. The method of claim 7 wherein the different metrology processes are performed simultaneously.

9. A method of processing substrates comprising:
grouping substrates of a plurality of small lot size substrate carriers as a logical lot and at least one sub-lot;
processing the logical lot as if the substrates were stored in a single substrate carrier;
simultaneously dispatching the substrate carriers of the sub-lot to a plurality of metrology tools; and
simultaneously performing metrology on a plurality of substrates of the substrate carriers of the sub-lot.

10. The method of claim 9 wherein each substrate carrier is adapted to hold a maximum of 6 or fewer substrates.

11. The method of claim 9 wherein each substrate carrier is adapted to hold a maximum of 4 or fewer substrates.

12. The method of claim 9 wherein performing metrology includes performing a plurality of different metrology processes.

13. A method of processing substrates comprising:
grouping substrates of a plurality of small lot size substrate carriers as a logical lot and at least one sub-lot;
dispatching the substrate carriers of the logical lot to a plurality of processing tools; and
simultaneously processing the logical lot at the plurality of processing tools.

14. The method of claim 3 wherein each substrate carrier is adapted to hold a maximum of 6 or fewer substrates.

15. The method of claim 3 wherein each substrate carrier is adapted to hold a maximum of 4 or fewer substrates.
